(19) United States
(12) Patent Application Publication
(10) Pub. No.: US 2025/0133727 A1
(43) Pub. Date: Apr. 24, 2025

(54) DRAM DEVICE INCLUDING LOW CAPACITANCE BIT LINE AND SWITCHING INSULATING LAYER

(71) Applicant: TAESUNG ENVIRONMENTAL RESEARCH INSTITUTE CO., LTD., Ulsan (KR)

(72) Inventors: Gi Yeol YUN, Ulsan (KR); Seok Man KIM, Ulsan (KR); Chai Rok LIM, Ulsan (KR); Hyeok-Je JEONG, Gimhae-si (KR); Myung-Kon JO, Ulsan (KR)

(73) Assignee: TAESUNG ENVIRONMENTAL RESEARCH INSTITUTE CO., LTD., Ulsan (KR)

(21) Appl. No.: 18/678,674

(22) Filed: May 30, 2024

(30) Foreign Application Priority Data
Oct. 20, 2023 (KR) 10-2023-0141179
Nov. 28, 2023 (KR) 10-2023-0168224

(51) Int. Cl. H10B 12/00

(52) U.S. Cl. CPC H10B 12/482; H10B 12/315

(57) ABSTRACT

Provided is a semiconductor device including: a substrate; a plurality of bit lines located on the substrate and disposed in parallel in a first horizontal direction; a plurality of word lines located on the bit lines and disposed in parallel in a second horizontal direction substantially perpendicular to the first horizontal direction; a plurality of channel patterns located on the bit lines, spaced apart in a third horizontal direction and a fourth horizontal direction substantially perpendicular to the third horizontal direction; a gate insulating pattern located between the plurality of channel patterns and the plurality of word lines; a plurality of switching insulating layers respectively formed on upper surfaces of the plurality of channel patterns, a portion of which has a thickness that an electron can penetrate upon application of a voltage; and a plurality of control electrodes disposed in parallel to connect the plurality of switching insulating layers.

### CROSS-REFERENCE TO RELATED APPLICATION

This application claims priority to and the benefit of Korean Patent Applications No. 10-2023-0141179, filed on Oct. 20, 2023 and No. 10-2023-0168224, filed on Nov. 28, 2023, the disclosure of which is incorporated herein by reference in its entirety.

### BACKGROUND

### 1. Field of the Invention

The present invention relates to a semiconductor device, and more specifically, to a semiconductor device including a vertical channel transistor.

### 2. Discussion of Related Art

As the degree of integration of a semiconductor memory device increases, a cell structure is changing from 8F2 and 6F2 to 4F2 to reduce the area occupied by each unit cell in two dimensions. Thus, in response to the reduction in unit cell area, various methods of forming components such as transistors, bit lines, word lines, and capacitors have been proposed. Specifically, in order to implement the 4F2 cell structure, a semiconductor device including a vertical channel transistor which induces a vertical channel by disposing a source and a drain vertically has been proposed (Non-Patent Document 1).

However, in the semiconductor device in Non-Patent Document 1, since channel patterns were disposed at all crossing points of bit lines and word lines, too many channel patterns were connected to a single bit line. As a result, since the parasitic capacitance of the bit line increased, an increase in height for improving the capacitance of a cell capacitor was inevitable. Further, a sensing margin of a sense amplifier decreased. This caused the reliability of the semiconductor device to deteriorate and disadvantages in the process.

Further, in the semiconductor device in Non-Patent Document 1, since a vertical pillar and a capacitor were in direct contact, leakage current flowed during the data storage time, and accordingly, there was a disadvantage in that the retention time was short and thus frequent refreshing was required, and power was excessively consumed.

### RELATED-ART DOCUMENT

### Non-Patent Document

(Non-Patent Document 1) Chung et al., “Novel 4F2 DRAM Cell with Vertical Pillar Transistor (VPT),” 2011 Proceedings of the European Solid-State Device Research Conference (ESSDERC), 2011

### SUMMARY OF THE INVENTION

The present invention is directed to providing a vertical channel transistor which has high reliability and is easily manufactured as an increase in sensing margin and a decrease in cell capacitor height are achieved through a decrease in bit line capacitance, and a semiconductor device including the same.

The present invention is directed to providing a vertical channel transistor capable of increasing retention time and a semiconductor device including the same.

According to an aspect of the present invention, there is provided a semiconductor device including: a substrate; a plurality of bit lines located on the substrate and disposed in parallel in a first horizontal direction at predetermined intervals; a plurality of word lines located on the bit lines and disposed in parallel in a second horizontal direction substantially perpendicular to the first horizontal direction at predetermined intervals; a plurality of channel patterns located on the bit lines, spaced apart in a third horizontal direction different from the first and second horizontal directions and a fourth horizontal direction substantially perpendicular to the third horizontal direction, and extending in a vertical direction; a gate insulating pattern located between the plurality of channel patterns and the plurality of word lines; a plurality of switching insulating layers respectively formed on upper surfaces of the plurality of channel patterns, at least a portion of which has a thickness that an electron can penetrate upon application of a voltage; and a plurality of control electrodes disposed in parallel at predetermined intervals to connect the plurality of switching insulating layers.

In one embodiment, the plurality of control electrodes may be disposed in parallel in the second horizontal direction.

In one embodiment, the semiconductor device may further include spacer layers formed on at least portions of side surfaces of the plurality of channel patterns to electrically insulate the plurality of channel patterns and the plurality of control electrodes.

In one embodiment, when an interval between adjacent word lines is L₁, an interval between adjacent bit lines is L₂, and an angle formed by the first horizontal direction and the third horizontal direction is θ₁, tan θ₁ may be L₂/L₁.

In one embodiment, L₁ and L₂ may be substantially the same.

In one embodiment, the plurality of channel patterns located on a single bit line may be arranged in a straight line form in the first horizontal direction.

In one embodiment, when the total number of crossing points of the word lines and the bit lines is n₁, and the number of crossing points where the channel patterns are disposed is n₂, n₁/n₂ may be 2.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a vertical channel transistor according to one embodiment of the present invention;

FIG. 2 is a cross-sectional view taken along line A-A′ in FIG. 1;

FIG. 3 is a schematic plan view of the vertical channel transistor according to one embodiment of the present invention;

FIG. 4 is a perspective view of a semiconductor device including the vertical channel transistor according to one embodiment of the present invention;

FIG. 5 is a cross-sectional view of a vertical channel transistor according to a first modified example.

FIG. 6 illustrates an energy band inside a switching insulating layer.

### DETAILED DESCRIPTION OF EXEMPLARY EMBODIMENTS

Hereinafter, one aspect of the present specification will be described with reference to the accompanying drawings. However, the disclosed items of the present specification may be implemented in various different forms, and thus are not limited to the embodiments described herein.

Throughout the present specification, a case in which one part is “connected to” another part includes not only a case in which the one part is “directly connected to” another part but also a case in which the one part is “indirectly connected to” another part with another member therebetween. Further, a case in which a certain member is located “on,” “at an upper portion,” “at an upper end,” “under,” “at a lower portion,” or “at a lower end” includes not only a case in which the certain member is in contact with another member, but also a case in which still another member is present between the two members.

Throughout the present specification, a case in which a certain part “includes” a certain component means that other components may be further included, rather than excluding other components, unless otherwise specified.

Embodiments described in the present specification will be described with reference to cross-sectional views and/or schematic diagrams which are ideal exemplary views of the present invention. Further, the same reference numerals refer to the same components throughout the specification. In this case, detailed descriptions of known functions and configurations which may obscure the gist of the present invention are omitted. Further, in each drawing shown in the present invention, each component may be shown in a somewhat enlarged or downsized form in consideration of convenience of description.

In addition, the embodiments of the present invention are not limited to the specific forms shown, and also include changes in forms generated according to a manufacturing process.

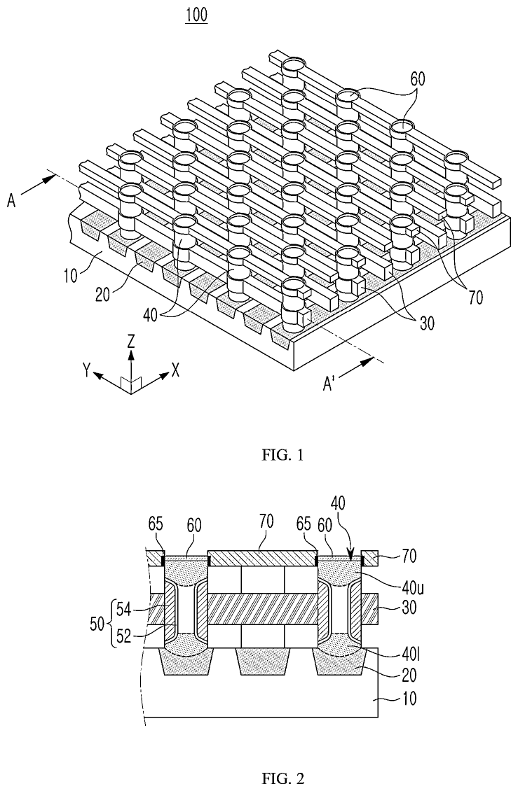

FIG. 1 is a perspective view schematically illustrating a vertical channel transistor according to one embodiment of the present invention.

Referring to FIG. 1, a vertical channel transistor 100 according to one embodiment of the present invention includes a substrate 10, a plurality of bit lines 20 located on the substrate 10 and disposed in parallel in a first horizontal direction at predetermined intervals, a plurality of word lines 30 located on the bit lines 20, and disposed in parallel in a second horizontal direction substantially perpendicular to the first horizontal direction at predetermined intervals, a plurality of channel patterns 40 located on the bit lines 20, spaced apart in a third horizontal direction different from the first and second horizontal directions and a fourth horizontal direction substantially perpendicular to the third horizontal direction, and each extending in a vertical direction, a gate insulating pattern (not shown) located between the plurality of channel patterns 40 and the plurality of word lines 30, a plurality of switching insulating layers 60 respectively formed on upper surfaces of the plurality of channel patterns 40, at least a portion of which has a thickness that an electron can penetrate upon application of a voltage, and a plurality of control electrodes 70 disposed in parallel at predetermined intervals to connect the plurality of switching insulating layers 60.

In the vertical channel transistor 100 according to one embodiment of the present invention, the plurality of bit lines 20 and the plurality of word lines 30 are arranged to cross each other. Each bit line 20 may be provided to extend in the first horizontal direction (for example, an x-axis direction), and each word line 30 may be provided to extend in the second horizontal direction (for example, a y-axis direction) crossing the first horizontal direction.

The plurality of channel patterns 40 are disposed at some of the points where the plurality of bit lines 20 and the plurality of word lines 30 cross.

Electrodes (not shown) may be respectively formed at the top and bottom of the plurality of channel patterns 40, a gate (not shown) may be formed to surround side surfaces between an upper electrode and a lower electrode, and the gate may be composed of the gate insulating pattern and a gate conductive pattern.

FIG. 2 is a cross-sectional view taken along line A-A′ in FIG. 1.

Referring to FIG. 2, the vertical channel transistor 100 includes the substrate 10, and the plurality of channel patterns 40 arranged on the substrate 10 in an array form. The channel pattern 40 may be arranged on a plane (for example, an xy plane) of the substrate 10 in a two-dimensional array form.

The substrate may include, for example, group IV semiconductor materials such as silicon (Si), germanium (Ge), silicon germanium (SiGe), and silicon carbide (SiC), group III-V semiconductor materials such as gallium arsenide (GaAs), indium arsenide (InAs), and indium phosphide (InP), an oxide semiconductor, a nitride semiconductor, a nitride oxide semiconductor, or the like. Specifically, the substrate may be a silicon substrate doped with n-type impurities, but is not limited thereto.

Each of the plurality of channel patterns 40 may be provided to extend substantially vertically from the substrate 10. Here, each channel pattern 40 may be provided to protrude substantially vertically from an upper surface of the substrate 10. Each channel pattern 40 is formed integrally with the substrate 10, and thus may include the same semiconductor material as the substrate 10.

Each of the plurality of channel patterns 40 may include a source region as an upper electrode 40u and a drain region as a lower electrode 40l. The lower electrode 40l may be electrically connected to the bit line 20, and the upper electrode 40u may be electrically connected to a capacitor (not shown), which will be described below. The positions of the source region and the drain region may be changed as needed, and the upper electrode 40u may function as the drain region and the lower electrode 40l may function as the source region.

In the channel pattern 40, a region between the upper electrode 40u and the lower electrode 40l is a body region (not shown) and has the same polarity as the substrate 10, and the upper electrode 40u and the lower electrode 40l have a different polarity from the substrate 10. For example, when the substrate 10 is a p-type semiconductor substrate, the body region has a p-type polarity, and each of the upper electrode 40u and the lower electrode 40l has an n-type polarity. In this case, the upper electrode 40u and the lower electrode 40l may be formed by injecting n-type impurity ions into each of the top and bottom of the channel pattern 40, and performing drive-in diffusion.

A gate 50 is formed between the upper electrode and the lower electrode to surround the side surfaces of the channel pattern 40, and the gate 50 may be composed of a gate insulating pattern 52 and a gate conductive pattern 54.

According to one embodiment, at least a portion of each channel pattern 40 may be in direct contact with the substrate 10, and in this case, a back bias may be transmitted to each channel pattern 40 to suppress a phenomenon called a floating body effect. The contact region between each channel pattern 40 and the substrate 10 is not specifically limited, but for example, may be any one of an outer portion and a center portion of each channel pattern 40.

The bit lines 20 may be provided to extend along the first horizontal direction (for example, the x-axis direction) under the lower electrodes 401, and each bit line 20 may electrically connect the lower electrodes 401 arranged along the first horizontal direction. The bit line 20 is formed in the substrate 10, and thus may include the same semiconductor material as the substrate 10.

Each of the plurality of word lines 30 is provided to correspond to the gate 50 formed on the side surfaces of the channel pattern 40. Specifically, each word line 30 may be provided to surround the gate 50.

The word line 30 may include a conductive material. For example, the word line 30 may include at least one or more among a metal, a semiconductor, and an alloy. Specifically, the word line 30 may include one or more metals selected from the group consisting of aluminum, tungsten, molybdenum, titanium, and tantalum, and one or more semiconductors selected from the group consisting of a group IV semiconductor, a group III-V semiconductor, an oxide semiconductor, a nitride semiconductor, and a nitride oxide semiconductor, but is not limited thereto.

A plurality of switching insulating layers 60 are each formed on an upper surface of each of the plurality of channel patterns 40, at least a portion of which has a thickness that an electron can penetrate upon application of an external voltage.

According to conventional vertical channel transistors, the channel pattern is in direction contact with the cell capacitor, causing leakage current to flow during data storage.

Accordingly, the semiconductor device has a short retention time, requiring frequent data refresh operations.

However, according to the present invention, the switching insulating layer 60 is formed on the upper surface of the channel pattern 40. Accordingly, current flows between the channel pattern and the capacitor by tunneling, channeling, etc., upon application of an external voltage during data recognition, whereas leakage current generation is suppressed during data storage, resulting in extended retention time. Thereby, cells can normally operate during data storage and during data recognition, data retention characteristics are improved, and also power consumption can be reduced. In addition, extended retention time allows a cell capacitor to have a smaller height, which facilitates manufacturing and scaling down.

The switching insulating layer 60 may include one or more selected from the group consisting of silicon oxide (SiO₂), titanium oxide (TiO₂), aluminum oxide (Al₂O₃), nickel oxide (NiO, NiO₂, and Ni₂O₃), copper oxide (Cu₂O and CuO), zirconium oxide (ZrO₂), manganese oxide (MnO, MnO₂, Mn₂O₃, Mn₃O₄, and Mn₂O₇), hafnium oxide (HfO₂), tungsten oxide (WO, WO₂, WO₃, and W₂O₃), tantalum oxide (Ta₂O₅), niobium oxide (Nb₂O₅), and iron oxide (FeO, Fe₂O₃, and Fe₃O₄), but is not limited thereto.

The thickness of the switching insulating layer 60 is not particularly limited as long as it can provide a pathway for electrons to move by tunneling, channeling, etc. The switching insulating layer 60 may have a thickness, e.g., 1 nm or less.

The plurality of control electrodes 70 are disposed parallel to each other at predetermined intervals to connect the plurality of switching insulating layers 60. The plurality of control electrodes 70 may be formed to enclose a side surface of each switching insulating layer 60. The plurality of control electrodes 70, which are for controlling the movement of electrons through the switching insulating layer, modify an energy band of the switching insulating layer 60 during data recognition, thereby helping electrons to move by tunneling, channeling, etc.

In the case where only the switching insulating layer 60 is formed between the channel pattern 40 and the capacitor, sufficient current flow can hardly be expected during data recognition. However, according to the present invention, a plurality of control electrodes 70 connecting the plurality of switching insulating layers 60 are arranged, and current is applied to the plurality of control electrodes 70 during data recognition, thereby achieving smooth current flow.

In an example, a plurality of control electrodes 70 may be disposed parallel to each other in a second horizontal direction. In other words, the plurality of control electrodes 70 may extend in the same direction as a plurality of word lines 30. In this case, the flow of current can be controlled smoothly by applying current to control electrodes arranged on word lines to which current is applied, while not applying current to control electrodes arranged on word lines to which current is not applied.

In an example, the control electrode 70 may have a thickness greater than the thickness of the switching insulating layer 60, e.g., a thickness of greater than 1 nm and 2 nm or less, but is not limited thereto. In this case, electrons in the switching insulating layer 60 may move smoothly by tunneling, channeling, etc.

In an example, a spacer layer 65 may be further comprised, which is formed on at least a portion of a side surface of the plurality of channel patterns 40 (e.g., an upper part of the channel pattern 40) to electrically insulate the plurality of channel patterns 40 from the plurality of control electrodes 70. The spacer layer 65 may extend to at least a portion of a side surface of the switching insulating layer 60, but is not limited thereto.

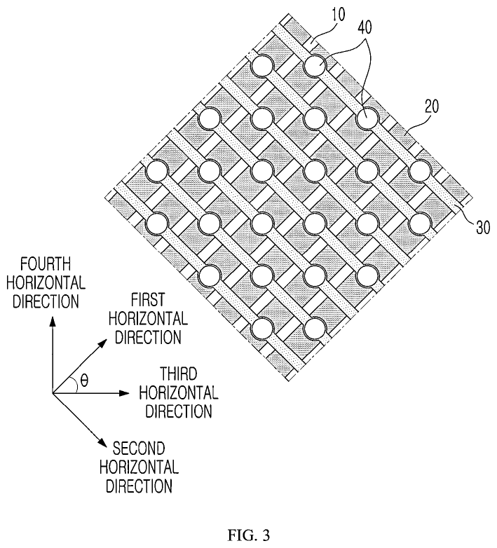

FIG. 3 is a schematic plan view of the vertical channel transistor according to one embodiment of the present invention.

Referring to FIG. 3, the plurality of channel patterns 40 may be formed to be spaced apart from each other in a third direction different from the first horizontal direction in which the plurality of bit lines 20 are formed to extend and the second horizontal direction in which the plurality of word lines 30 are formed to extend and a fourth horizontal direction substantially perpendicular to the third horizontal direction.

In a conventional vertical channel transistor, the formation directions of the bit lines and word lines (for example, an x-axis direction and a y-axis direction) and the arrangement directions of a channel pattern array (for example, the x-axis direction and the y-axis direction) coincided. In other words, since channel patterns were connected to all crossing points of the bit lines and the word lines, too many channel patterns were connected to a single bit line. As a result, since the parasitic capacitance of the bit lines increased, an increase in height for improving capacitance of a cell capacitor was inevitable. Further, a sensing margin of a sense amplifier decreased. This caused the reliability of the semiconductor device to deteriorate and disadvantages in the process.

However, in the present invention, as the plurality of channel patterns 40 are arranged in directions different from the formation directions of the bit lines 20 and the word lines 30, since the number of channel patterns disposed on a single bit line is reduced and the number of cell transistors is reduced, the parasitic capacitance of the bit lines decreases. As a result, since the sensing margin of the sense amplifier may increase or height of the cell capacitor may be reduced, there is an advantage in that reliability increases, manufacturing is easy, and scaling down is easy.

According to one example, when an interval between adjacent word lines is L₁, an interval between adjacent bit lines is L₂, and an angle formed by the first horizontal direction and the third horizontal direction is θ₁, tan θ₁ may be L₂/L₁. Here, the interval between adjacent word lines refers to a length of a line segment which connects center portions of two adjacent word lines when an imaginary line extending in the first horizontal direction from an arbitrary point is drawn, and the interval between adjacent bit lines refers to a length of a line segment which connects center portions of two adjacent bit lines when an imaginary line extending in the second horizontal direction from an arbitrary point is drawn. In this case, since neighboring bit lines do not share word lines, there is an advantage in that a cell array with a folded bit line structure is possible. In the folded bit line structure, since stable data sensing may be performed, a size of the cell array may be increased, and a sense amplifier region may be reduced, it may be advantageous in terms of cell efficiency.

When tan θ₁ has a value greater than L₂/L₁, it is inevitable the bit line spacing should be reduced to dispose the same number of cells in the same area, and as a result, the capacitance between neighboring bit lines may increase and the difficulty of the bit line formation process may increase. On the other hand, when tan θ₁ has a value of L₂/L₁, since the bit line spacing is relatively wide, there is an advantage in that the capacitance between neighboring bit lines is low, and bit line formation is easy.

According to one example, L₁ and L₂ may have substantially the same value. In this case, the bit line capacitance may be minimized, and as a result, there is an advantage in that the height of a capacitor disposed on the vertical channel transistor may be reduced, and scaling down becomes easier.

According to one example, the plurality of channel patterns located on a single bit line may be arranged in a straight line form in the first horizontal direction. In this case, since the number of channel patterns disposed on the single bit line decreases and the number of cell transistors decreases, the parasitic capacitance of the bit line may decrease. As a result, there is an advantage in that the height of the capacitor disposed on the vertical channel transistor may be reduced, and scaling down becomes easier.

According to one example, when the total number of crossing points of the word lines and the bit lines is n₁, and the number of crossing points where the channel patterns are disposed is n₂, n₁/n₂ may be 2. Here, n₁/n₂ may refer to a value obtained by adding 1 to the number of crossing points located between adjacent channel patterns on a single bit line. When n₁/n₂ has a value greater than 2, it is inevitable the bit line spacing should be reduced to dispose the same number of cells in the same area, and as a result, the capacitance between neighboring bit lines may increase and the difficulty of the bit line formation process may increase. On the other hand, when n₁/n₂ has a value of 2, since the bit line spacing is relatively wide, there is an advantage in that the capacitance between neighboring bit lines is low, and bit line formation is easy.

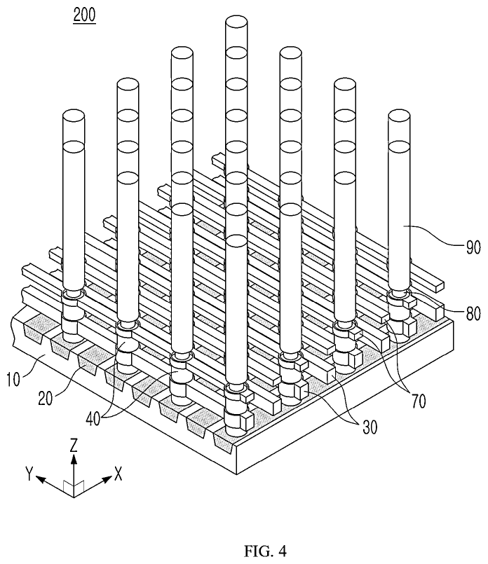

FIG. 4 is a perspective view schematically illustrating a semiconductor device including the vertical channel transistor according to one embodiment of the present invention. Referring to FIG. 4, a capacitor 90 may be connected to an upper portion of the vertical channel transistor 100, and accordingly, a semiconductor device 200 such as a dynamic random access memory (DRAM) may be implemented.

The capacitor 90 may be electrically connected to the channel pattern 40, and a contact plug 80 may be further included between the capacitor 90 and the channel pattern 40. The vertical channel transistor 100 may be used in a non-memory device such as a central processing unit (CPU) in addition to the memory described above.

In the present invention, a method of manufacturing a vertical channel transistor and a semiconductor device including the same is not particularly limited, but for example, the vertical channel transistor and the semiconductor device may be manufactured using the following method.

On a substrate 10, a plurality of channel patterns 40 with electrodes 40u and 401 formed at the top and bottom thereof and extending in a substantially vertical direction are formed. The upper electrodes 40u of the plurality of channel patterns 40 may be, for example, source regions, and the lower electrodes 401 of the plurality of channel patterns 40 may be, for example, drain regions.

The plurality of channel patterns 40 may be arranged on the plane (for example, an xy plane) of the substrate 10 in a two-dimensional array form, and specifically, may be spaced apart from each other on the plane (for example, the xy plane) of the substrate 10 in the third horizontal direction and the fourth horizontal direction substantially perpendicular to the third horizontal direction to be arranged in a two-dimensional array form.

Next, gates 50 are formed to surround side surfaces between the upper electrodes 40u and the lower electrodes 401 of the plurality of channel patterns 40. The gate 50 may include a gate insulating pattern 52 and a gate conductive pattern 54.

Next, a plurality of bit lines 20 are formed to commonly come into contact with the lower electrodes 401 of the plurality of channel patterns 40. Here, the bit line 20 may be formed in the first horizontal direction (for example, the x-axis direction in FIG. 1) different from the third horizontal direction and the fourth horizontal direction.

Next, a plurality of word lines 30 are formed to commonly come into contact with the gates 50 formed on the side surfaces of the plurality of channel patterns 40. Here, the word lines 30 may be formed in the second horizontal direction (for example, the y-axis direction in FIG. 1) substantially perpendicular to the first horizontal direction.

Next, a plurality of switching insulating layers 60 at least partially having a thickness through which electrons can tunnel are formed on the upper surfaces of the plurality of channel patterns 40. Here, the thickness through which electrons can tunnel may refer to 1 nm or less, but is not limited thereto.

Next, spacer layers 65 are formed on at least portions of the side surfaces of the plurality of channel patterns 40 (for example, the top of the channel patterns 40). The spacer layer 65 may extend to at least a portion of the side surface of the switching insulating layer 60, but is not limited thereto. The spacer layers 65 may serve to electrically insulate the plurality of channel patterns 40 and the plurality of control electrodes 70.

Next, a plurality of control electrodes 70 are formed to commonly come into contact with the plurality of switching insulating layers 60. Here, the control electrodes 70 may be formed in the same direction as the word lines 30, that is, in the second horizontal direction.

Thereafter, the manufacture of the vertical channel transistor according to the present invention and the semiconductor device including the same may be completed by sequentially performing a series of known follow-up processes.

### First Modified Example

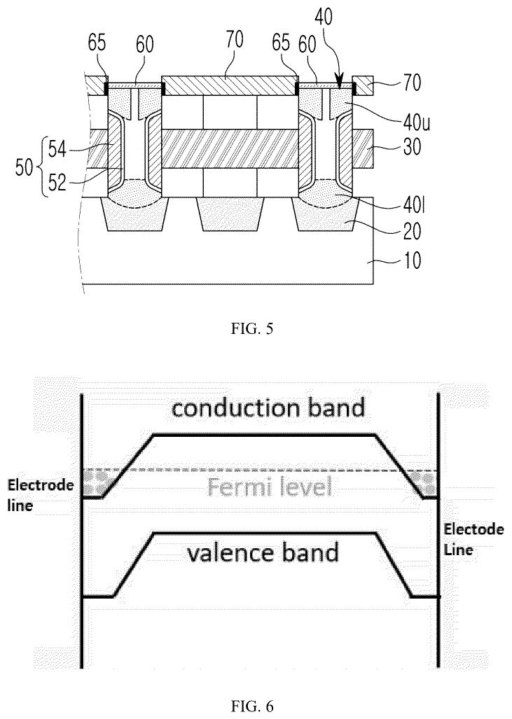

FIG. 5 is a cross-sectional view of a vertical channel transistor according to a first modified example. In FIG. 5, the same components as those of the above-described embodiment are given the same reference numerals and descriptions thereof will be omitted or simplified.

In the first modified example, as a body region of the channel pattern 40 passes through at least a portion of the upper electrode 40u, the channel pattern 40 directly comes into contact with the switching insulating layer 60, and in this case, there is an advantage in that the floating phenomenon of the switching insulating layer 60 may be prevented.

The body region passing through the upper electrode 40u may be formed by an implantation process after forming the upper electrode 40u, or may be formed by injecting n-type impurity ions and performing drive-in diffusion after disposing a mask having a predetermined opening pattern on the body region when forming the upper electrode 40u.

The contact region between the body region and the switching insulating layer 60 is not specifically limited, but for example, may be any one of an outer portion and a center portion of each channel pattern 40.

The technical reasons why smooth current flow can be achieved by applying current to a control electrode are described in more details below.

First, for the case where only the switching insulating layer is formed between the channel pattern and the capacitor, a change in current density according to a potential difference between the channel pattern and the capacitor is described below.

The current-voltage characteristics for the physical thicknesses of the SiO₂ layer that is widely used as an insulating layer in the field of DRAM devices are illustrated in FIG. 1.1 in the paper (Muhammad Mustafa Hussain, ADVANCED FABRICATION PROCESSES FOR SUB-50 nm CMOS, The university of Texas at Austin, December 2005). Referring thereto, when changing the potential difference from 0 V to 3 V, the current density increases about 10⁸ fold for the thickness of 1.5 nm and about 10⁷ fold for the thickness of 2 nm. That is, it can be expected that a change in current density of about 10⁷ fold or more, at least 10⁶ fold or more can be achieved without the help of the control electrode, when the switching insulating layer has a thickness that can provide a pathway for electrons to move by tunneling, channeling, etc.

Next, a change in density current according to application of current to the control electrode is described below. FIG. 5 illustrates an energy band inside a switching insulating layer.

The Fermi level lies approximately in the middle of the energy band gap. When the bottom of the conduction band is lower than the Fermi level, electrons are concentrated in the conduction band, and a movement pathway of electrons is formed. As the switching insulating layer has a very small thickness, the electrons concentrated in the conduction band may come from the contact plug (storage node) that the switching insulating layer contacts or from the upper electrode (n+ region), as well as from inside the switching insulating layer.

For example, when applying a voltage of about 5 V to the control electrode, the bottom of the conduction band is located below the Fermi level (4.55 V) since the energy band gap of the SiO₂ layer is 9.1 V. If a substance having a small energy band gap (e.g., high-k substance), not SiO₂, is used for the switching insulating layer, a movement pathway of electrons may be formed even when the voltage applied to the control electrode is 5 V or less.

Once a movement pathway of electrons is formed in the conduction band, the electrons move from the conduction band, and current flows according to the equation V=IR. A much larger amount of current than the amount of current by tunneling, etc., flows.

Accordingly, it can be easily expected that a change in current density in the conduction band is significantly greater (at least 10⁶ fold or greater) than the change in current density by tunneling.

Next, current by the control electrode and current in a DRAM cell are compared. When the capacitance Cs of a DRAM cell capacitor is 5 fF, a drive voltage is 1 V, and a write time is 10 ns, the current in the DRAM cell can be calculated as below.

$$[ Equation 1 ]$$

$$\frac{\begin{matrix}capacitor capacitance per cell \times \\ drive voltage\end{matrix}}{Write time} = \frac{5 \times 1 {0}^{- 15} F \times 1 V}{10 \times 1 {0}^{- 9} sec} = 0.5 μA$$

In FIG. 1.1 in the paper described above, the current density is about 20 A/cm² when the thickness of the SiO₂ layer is 1.5 nm, and the drive voltage is 1 V. Accordingly, the current (current passing through the switching insulating layer when a voltage is not applied to the control electrode) can be calculated by multiplying said current density by the cross-sectional area of the channel pattern (radius of 7 nm), as indicated below.

$$[ Equation 2 ]$$

$$Gate current density = 20 A / {cm}^{2} \times π \times {( 7 \times {10}^{- 7} cm )}^{2} = 3.0772 \times 1 {0}^{- 11} A$$

When multiplying the obtained current value by the change in current density 10⁶ fold, it is calculated as 30.772 μA. This value is greater than 0.5 μA, which is the current in the DRAM cell. Considering the change in current density in the conduction band is significantly greater than the change in current density by tunneling, as described above, it can be confirmed that modification of the conduction band by the control electrode may allow sufficient current flow in the DRAM cell.

A semiconductor device according to one aspect of the present invention has an advantage in that a sensing margin of a sense amplifier can increase as the parasitic capacitance of bit lines is lowered, and accordingly, reliability is excellent.

Further, a semiconductor device according to one aspect of the present invention has an advantage in that a height of a cell capacitor can be decreased, and thus manufacturing and scaling down are easy.

In addition, a semiconductor device according to one aspect of the present invention has an advantage in that the generation of leakage current is suppressed and the retention time is long.

In addition, a semiconductor device according to one aspect of the present invention has an advantage in that data retention characteristics are excellent and power consumption is low.

The effects of the one aspect of the present invention are not limited to the above-described effects, and should be understood as including all effects which can be inferred from configurations described in the detailed descriptions of the present specification or claims.

The above description of the present specification is provided for illustrative purposes, and those skilled in the art should understand that the present specification may be easily modified into other specific forms without changing the technical spirit or essential features disclosed in the present specification. Accordingly, the above-described embodiments should be understood as being exemplary and not limiting. For example, each component described as a singular form may be implemented in a distributed form, and similarly, components described as a distributed form may also be implemented in a combined form.

The scope of the present specification is indicated by the following claims, and all changes or modifications derived from the meaning and the scope of the claims and equivalents thereof should be understood as being within the scope of the present specification.

### LIST OF REFERENCE NUMERALS

10: substrate
20: bit line
30: word line
40: channel pattern
40l: lower electrode
40u: upper electrode
50: gate
52: gate insulating pattern
54: gate conductive pattern
60: switching insulating layer
65: spacer layer
70: control electrode
80: contact plug
90: capacitor
100: vertical channel transistor
200: semiconductor device

What is claimed is:

1. A semiconductor device comprising:
a substrate;
a plurality of bit lines located on the substrate and disposed in parallel in a first horizontal direction at predetermined intervals;
a plurality of word lines located on the bit lines and disposed in parallel in a second horizontal direction substantially perpendicular to the first horizontal direction at predetermined intervals;
a plurality of channel patterns located on the bit lines, spaced apart in a third horizontal direction different from the first and second horizontal directions and a fourth horizontal direction substantially perpendicular to the third horizontal direction, and extending in a vertical direction;
a gate insulating pattern located between the plurality of channel patterns and the plurality of word lines;
a plurality of switching insulating layers respectively formed on upper surfaces of the plurality of channel patterns, at least a portion of which has a thickness that an electron can penetrate upon application of a voltage; and
a plurality of control electrodes disposed in parallel at predetermined intervals to connect the plurality of switching insulating layers.

2. The semiconductor device of claim 1, wherein the plurality of control electrodes are disposed in parallel in the second horizontal direction.

3. The semiconductor device of claim 1, further comprising spacer layers formed on at least portions of side surfaces of the plurality of channel patterns to electrically insulate the plurality of channel patterns and the plurality of control electrodes.

4. The semiconductor device of claim 1, wherein, when an interval between adjacent word lines is L₁, an interval between adjacent bit lines is L₂, and an angle formed by the first horizontal direction and the third horizontal direction is θ₁, tan ƒ₁ is L₂/L₁.

5. The semiconductor device of claim 4, wherein L₁ and L₂ are substantially the same.

6. The semiconductor device of claim 1, wherein the plurality of channel patterns located on a single bit line are arranged in a straight line form in the first horizontal direction.

7. The semiconductor device of claim 1, wherein, when the total number of crossing points of the word lines and the bit lines is n₁, and the number of crossing points where the channel patterns are disposed is n₂, n₁/n₂ is 2.
